(19) United States
(12) Patent Application Publication
(10) Pub. No.: US 2013/0017647 A1
(43) Pub. Date: Jan. 17, 2013

(54) SURFACE-MODIFIED NANOPARTICLE INK FOR PHOTOVOLTAIC APPLICATIONS

(71) Applicants: James P. Novak, Austin, TX (US); Yunjun Li, Austin, TX (US)

(72) Inventors: James P. Novak, Austin, TX (US); Yunjun Li, Austin, TX (US)

(73) Assignee: APPLIED NANOTECH HOLDINGS, INC., Austin, TX (US)

(21) Appl. No.: 13/545,699

(22) Filed: Jul. 10, 2012

Related U.S. Application Data
(60) Provisional application No. 61/507,301, filed on Jul. 13, 2011.

(51) Int. Cl. H01L 31/18

(52) U.S. Cl. 438/98; 257/E31.119

(57) ABSTRACT

Described herein is a novel material that easily penetrates silicon nitride-based anti-reflective coatings, forming a high quality electrical contact. A method for metallization on a solar cell includes depositing a passivation layer on a silicon substrate of a solar cell, depositing derivatized metal particles onto the passive layer, heating the substrate of the solar cell to migrate surface coatings from the derivatized metal particles onto the passivation layer creating a diffusion Channel through passivation layer to the silicon substrate, and as the metal particles melt due to the heating on the substrate, the melted metal diffuses through the diffusion channel forming a metallic content with the silicon substrate.

This application claims priority to U.S. Provisional Application Ser. No. 61/507,301, which is hereby incorporated by reference herein.

### TECHNICAL FIELD

This invention is related in general to solar cells.

### BACKGROUND INFORMATION

Silicon solar cells for photovoltaic applications utilize metal contact electrodes to extract: the electrical power from the silicon. A simplified solar cell manufacturing process involves several steps. A purified silicon ingot is cut into wafers. The individual silicon wafers are then doped according to the desired cell structure. Additional surface coatings are then deposited onto the cell. These coatings include passivation and anti-reflective coatings. By design the specialized coatings are engineered to mostly non-reactive and impenetrable. Metallic contacts are then added on top of these specialized coatings. A problem with this manufacturing process is that the specialized coatings, as well as formation of oxides on the metallic contacts layer during high-temperature processes, prevent quality electrical contacts from forming between the metal contacts and the underlying silicon. Quality electrical contacts are characterized by low sheet resistance and low contact resistivity, and are essential for achieving high solar cell fill factor and efficiency.

Silicon solar cells can be manufactured utilizing two distinctly different architectures: with either top electrical contacts or bottom electrical contacts. Bottom electrical contact solar cells may use interdigitated back contacts (“IBC”) electrode designs. These IBC cells typically exhibit excellent efficiency, as the electrical contacts are placed on the backside of the solar cell, which eliminates shadowing effects where the electrical contacts block a portion of the light (e.g., sunlight) from reaching the cells. They may also increase the pin junction area and reduce recombination lengths, meaning more separated electron hole pairs are collected to perform electrical work. However, bottom contact solar cells are generally more expensive to manufacture than top contact solar cells.

Top contact solar cells are generally formed onto p-type silicon wafers. The topside of the wafer may he doped with n-type diffusion methods using phosphorous. The topside of the wafer may then be coated with an anti-reflective coating (“ARC”), such as silicon nitride (SiN, SiₓN_{y}). The metal electrodes are then placed onto the silicon wafer. The backside (the p contact) may be coated with aluminum paste using a screen-printing method. The aluminum electrode may cover the entire backside of the silicon wafer. The topside electrodes (the a contact) may also be screen printed. The electrode pattern may take the shape of “fine fingers” connected to a buss bar. The area of the solar cell that is covered by the top contact does not receive light. This shadowing effect may he minimized by narrowing the widths of the electrode buss bar and “finger-like” electrodes.

A prominent challenge in the manufacture of silicon solar cells is the formation of the top contacts. A quality ohmic contact is required for proper solar cell function however, the ARC layer is, by nature, highly resistant to chemicals; for example, silicon nitride is commonly used as a harrier layer to metal penetration in the fabrication of electronic devices. The placement of metallic pastes on top of a silicon nitride layer creates challenges whereby the metal cannot easily make electrical contact with the silicon underneath the ARC. Metallic pastes used for the formation Of top contacts contain complex glass frit, materials, whereby the glass frit melts at high temperature, reacts with the nitride passivation layer and provides a route for metal diffusion to establish a contact.

### BRIEF DESCRIPTION OF THE DRAWINGS

FIG. 1 illustrates a nanoparticle modified to react through a passivation layer, such as on a solar cell.

FIG. 2 illustrates a nanoparticle modified with a surface layer for doping, such as in a solar cell.

FIG. 3 illustrates a nanoparticle modified with a multi-functional surface layer, which reacts to form a diffusion channel and diffuses metals for doping a silicon substrate.

### DETAILED DESCRIPTION

Metallization for silicon solar cells may be in several forms. Metallization methods include direct deposition of a metal material using mask materials, and vacuum deposition techniques such as plasma vapor deposition or an evaporation process. Metallization layers may be deposited using chemical precursors that decompose in a reducing atmosphere to form the metallization layer. Another manufacturing method uses metallic paste materials. These pastes may be printed using a screen-printing method to form specific patterns for electrical contacts.

Such ink and paste materials may he manufactured using metallic particles, solvents, binders, and dispersants. It is challenging to find the right combination of ingredients that can stabilize the metal particles. Paste materials have a high viscosity for screen printing. This high viscosity allows for stabilization of large particles (which range in size from 0.5 to several microns in diameter) against gravitational settling. These particles may be manufactured by milling larger volumes of metal material down to these smaller micron powders. The micron powders are then mixed with the required ingredients to form a paste that can be screen printed.

Currently used methods for manufacturing solar cells are transitioning away from screen printing. This is due to requirements for more narrow line widths to reduce the shadowing effects. Alternative metallization methods to screen printing include inkjet and spray coatings (including utilization of an Optomec Aerosol Jet® device) of metallic inks, which provide distinct advantages compared with screen printing. For example, these methods do not physically touch the wafer during the printing process. This allows for use of thinner silicon wafers, which reduces materials usage and provides some gains in efficiency. Such printing methods achieve narrower line widths compared to screen printing. And, the non-contact printing techniques print thinner lines with higher conductivities, allowing for a comparable electrical performance but with a greatly reduced usage of materials. Each of these defines a new approach to reduce the manufacturing cost of Si PV (silicon photovoltaic) devices.

The ink materials that are compatible with non-contact printing techniques have unique requirements that easily distinguish themselves from screen-printed pastes. First, ink materials require much smaller particle sizes. In general, an ink has a lower viscosity than a paste. However, this decrease in viscosity reduces the stabilization effects against gravitational settling offered by pastes. Generally, metallic nanoparticles with dimensions below 300 nm are required to make such metallic ink materials. Non-contact printing techniques utilize finite nozzles that distribute the ink to the substrate surface. The nozzle size for a typical inkjet print head is less than 200 microns. Because the metallic particles tend to slightly aggregate in solution, the hydrodynamic diameters of these clusters are typically larger than their primary particle size.

Metallic nanoparticles have different properties compared to their bulk counterparts. These properties are also size dependent. For example, it is well-known that metallic nanoparticles absorb light and can have melting points well below their bulk materials counterparts. The wavelength of the absorbance spectrum becomes shorter as the particle size decreases. This is a function of increased surface energy of the smaller particles. This small size, and increased surface energy, also provides a mechanism for chemical functionalization to occur on the surface of the metal particle. It is such a specific chemical surface modification that is a focus of embodiments of the present invention.

The following describes aspects of a metallization process. As previously noted, top contact solar cells are commonly manufactured using a screen printing process. Typically, an aluminum electrode layer is deposited onto the backside “collector” of the silicon solar cell. Aluminum paste is applied using screen printing. The exposed silicon has a native oxide layer. The aluminum paste may have glass frit particles added to reduce thermal expansion and wafer “bowing,” which can be detrimental to final assembly of the solar cell however, this glass hit reduces the electrical conductivity of the electrode layer reducing the efficiency of the solar cell by adding series resistance to the equivalent circuit. The glass frit also reduces the contact resistivity of the aluminum-to-silicon interface.

As previously noted, the top side of a typical silicon solar cell is generally manufactured using Ag (silver) gridline contacts. These contacts are screen printed with a silver paste material. The silver paste is formulated with glass frit to facilitate the burn-through on the topside anti-reflective layer to make electrical contact with the underlying silicon.

As noted, screen printing solar cells is common practice. However, there arc limitations to the thickness of the solar cell wafers defined by the large area contact pressure of the screen and the linear pressure of the moving doctor blade (“squeegee”) during the printing process. This thickness threshold for screen printing silicon wafers is approximately 180 μm. Below this threshold, the wafers may he too fragile for reliable screen printing without regular damage to the wafers. Nevertheless, there are efficiency gains and materials cost savings that are realized by using thinner silicon wafers. It would he advantageous in the solar cell industry to manufacture silicon solar cells using less than 100 μm wafers. Such a shift will require new manufacturing techniques that can apply metallization layers without touching the solar cell wafer.

Examples of non-contact printing include, but are not limited to, inkjet, dispenser, and spray coatings. In each example, the print mechanism does not touch the wafer, and there is a transfer of material through the gap between the substrate and the print orifice, print mechanism or print nozzle. The printed material is an ink defined as a fluid media that contains the material of interest. One example of ink for solar cells includes metallic nanoparticles, a solvent, and dispersing agents. If hard particles arc used, they must be smaller than the opening in the print mechanism, such that they can pass through an orifice to transfer onto the substrate. In the inkjet printing example, the particles must pass through a piezo-electric nozzle. In the spray coatings example the particles must pass through a spray head.

Top contact solar cells are most commonly manufactured with silver metallic top contacts. As previously noted, the silver paste materials are specially formulated to react with the silicon nitride layer on the top of the cell. The most common method to ensure this reaction takes place is the addition of glass frit materials to the silver particles in the paste. The glass frit reacts at high, temperatures (e.g., >750° C.) with the silicon nitride layer, creating oxide or oxynitride diffusion Channels. This reaction process where reactive components in the metallization pastes allow for electrical contacts to be formed is commonly called “burn-through.” At these elevated temperatures, the metal (e.g., Ag) has a high mobility, can diffuse through the silicon nitride layer, and makes electrical contact to the silicon. While this creates electrical contacts, it creates a secondary problem.

The diffusion constant for silver in silicon is quite high. Once the silver penetrates the silicon nitride layer and makes contact with the silicon, it begins to diffuse through the silicon. At these elevated firing temperatures, the silver can diffuse through the silicon and across the p/n junction. This reduces the overall cell efficiency by providing a shunt pathway.

An alternative method to the “burn-through” process is to open up a via within the passivation layers. This can be accomplished using chemical etchants or laser scribing. Once there is an opening in the passivation layer, metal can be added directly in contact with the silicon forming an electrical contact. While this process can provide better electrical contact and thus increased efficiency, the overall manufacturing process involves additional steps requiring a larger capital equipment investment. The resulting power versus cost ratio is worse.

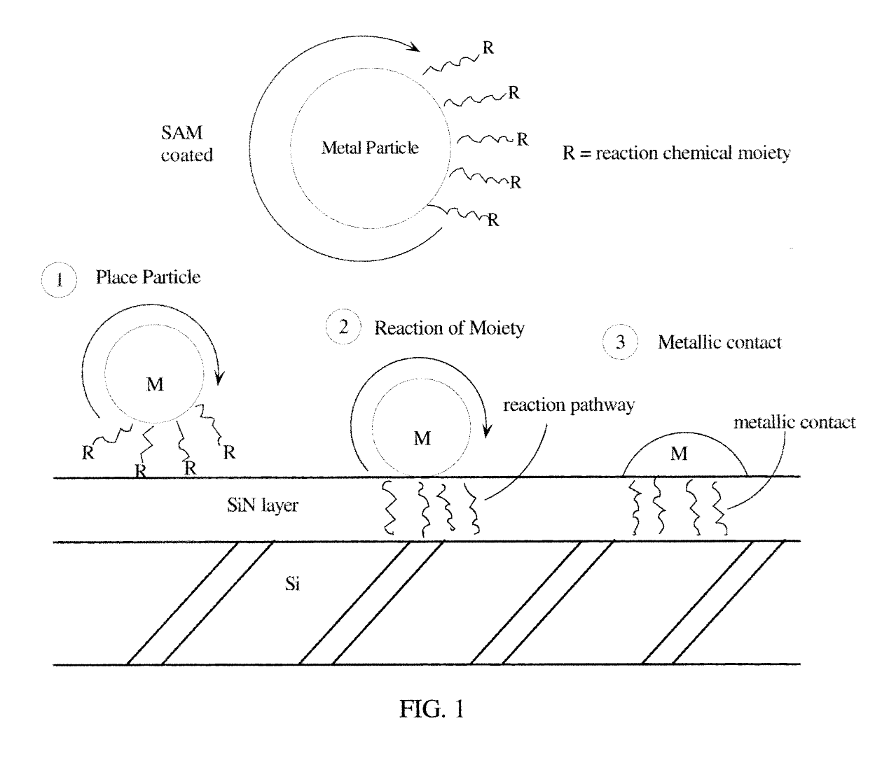

Embodiments of the present invention utilize specifically modified nanoparticles, which are configured to self-facilitate a reaction that creates an electrical contact through a passivation layer on solar cells. A similar process could be used on a silicon substrate to make a transistor or other solid-state electronic device. In the following embodiments illustrated in FIGS. 1-3, only a portion of the solar cell is shown for simplicity.

Referring to FIG. 1, a nanoparticle is modified to be able to react through a passivation layer onto a silicon substrate. The metal particle may he Ag, Al, Cu, or Ni. The passivation layer may be nitride or oxide based. The nanoparticle may be modified with a surface coating R containing a chemical functionality (reaction chemical moiety) that reacts with silicon nitride. The chemical functionality can be attached to the particle surface using a long chemical chain. Example of the chemical chain would he alkanes (—CH2)ₙ— where n is a number between 2 and 20, alkenes, poly alkenes, poly ethers or other linking group. The chemical chain is attached to the metal particle with a covalent attachment group in the example of thiol (mercaptan), siloxane, amine, amide, or an ionic attachment group in the example of amine, nitro, nitroso, amine, amid, etc. The reactive end, R, of the chemical functionality will react with the passivation layer on the surface. Examples include silicon oxide-based components, such as silanes, trisilanes, polysilanes, disilaethenes, siloxanes, siloxane oligomers, and polysiloxanes. These polymeric materials decompose into silicon-based glass materials to help facilitate the reaction with silicon nitride, allowing for a diffusion pathway of the metal to he formed. These silicon derivatives may be applied to a surface of the nanoparticle as a self-assembled monolayer (“SAM”). Additional SAM chemistry may include organo-borons, organo-phosphorous, organo-fluorine, and organo-chlorine compounds. This permits chemical functionality without changing the effective diameter of the particle and without the addition of bulk particles to the resulting ink solution. These SAMs may also be used to increase the solubility of the nanoparticles in its ink formulation. These SAMs may also be used to prevent oxidation of the metallic surface when exposed to oxygen. Additional metal-organic complexes may be used that decompose to create other metal oxide structures upon decomposition. The resulting metal oxides upon decomposition would include boron oxides, aluminum oxide, bismuth oxide tin oxides, strontium oxide, lanthanum oxide, magnesium oxides, zinc oxide, thallium oxides, lead oxides, and cadmium oxides.

Referring again to FIG. 1, the derivatized metal particle is placed on the surface. The substrate contains a passivation layer, which may he silicon nitride. The substrate is heated to a high temperature. The temperature is may be greater than 350° C. During the temperature ramp, the surface coating or SAM gains surface mobility on the metal particle due to thermal energy. This mobility occurs at a relatively low temperature of approximately 100° C. The SAM components migrate off the particle and onto the silicon nitride-coated substrate where they first decompose, react with ambient oxygen to create a metal oxide or glass like material and then react with the silicon nitride to form a diffusion channel. The decomposition of the SAM occurs at a temperature between 150° C. and 400° C. The reaction with the nitride can occur at a temperature beginning at 350° C. and increasing all the way to 900° C. During this process, the metal particle begins to melt, and the metal diffuses through the channel created by the chemical reaction and forms a contact with the silicon. The actual temperatures vary based upon the individual chemistry of the SAM.

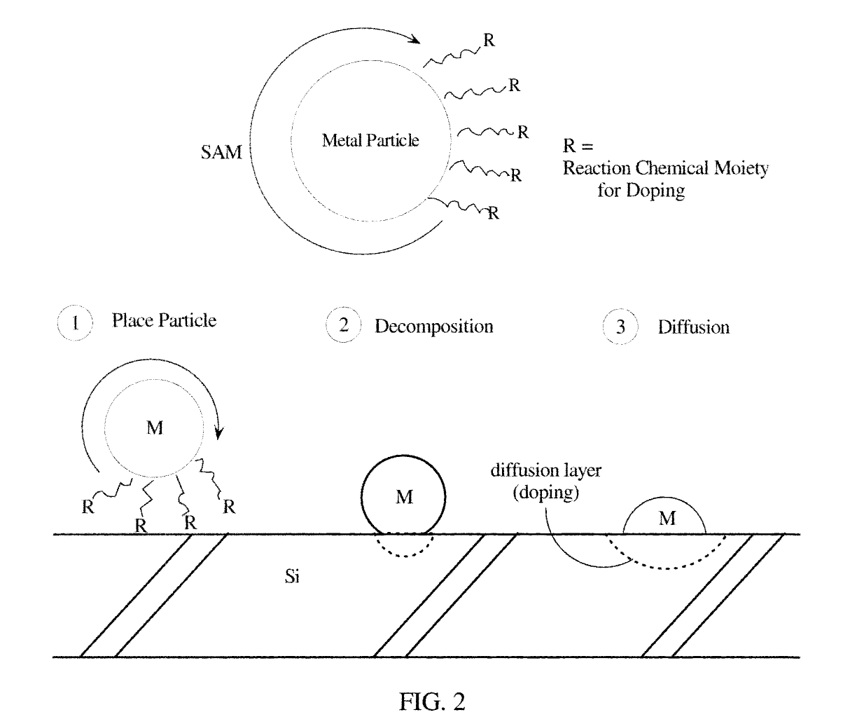

Referring to FIG. 2, in another embodiment, a nanoparticle is modified with a surface layer R that assists in doping the solar cell (i.e., a reactive chemical moiety for doping). The metal particle may be Ag, Al, Cu, or Ni. As an example, the metal nanoparticles may be coated with a SAM of organo-boron material. Examples of organo-phosphorous compounds include borates, boranes, diborenes, boron hydrides, and boron oxides. This organo-boron moiety makes contact, with the silicon where the metallic particle locally touches. Under high curing temperatures typically used to process the silicon solar cell metallic contacts, the SAM and the organo-boron will decompose. The boron diffuses through the silicon and locally dopes the silicon to be p⁺-type. Similarly, organo-phosphorous materials may be attached to the metal particle. Examples of organo-phosphorous compounds include phosphate esters, phosphonic acides, phosphinic acides, phosphonice esters, phosphinic esters, phosphonium salts, phosphoranes, phosphates, phosphonites, phosphinites, phosphines, etc. Specific examples include tri-phenyl phosphine and diphosphine components. Upon decomposition and phosphorous diffusion, the cell is doped n⁻-type. Such selective doping reduces the need for implantation steps, reducing the costs of solar cell manufacturing.

Referring again to FIG. 2, the derivatized metal particle is placed on the surface. The substrate is heated to a high temperature. The SAM gains surface mobility on the metal particle due to thermal energy. The SAM components migrate off the particle and onto the substrate where they react and diffuse into the silicon. This diffusion layer creates a local doping effect at the location of the particle placement. During this process, the metal particle begins to melt and the metal forms a contact at the exact location of the doping interface. Through this scenario the applied metallic ink with modified particles creates the doping and the metallic contact in once process step.

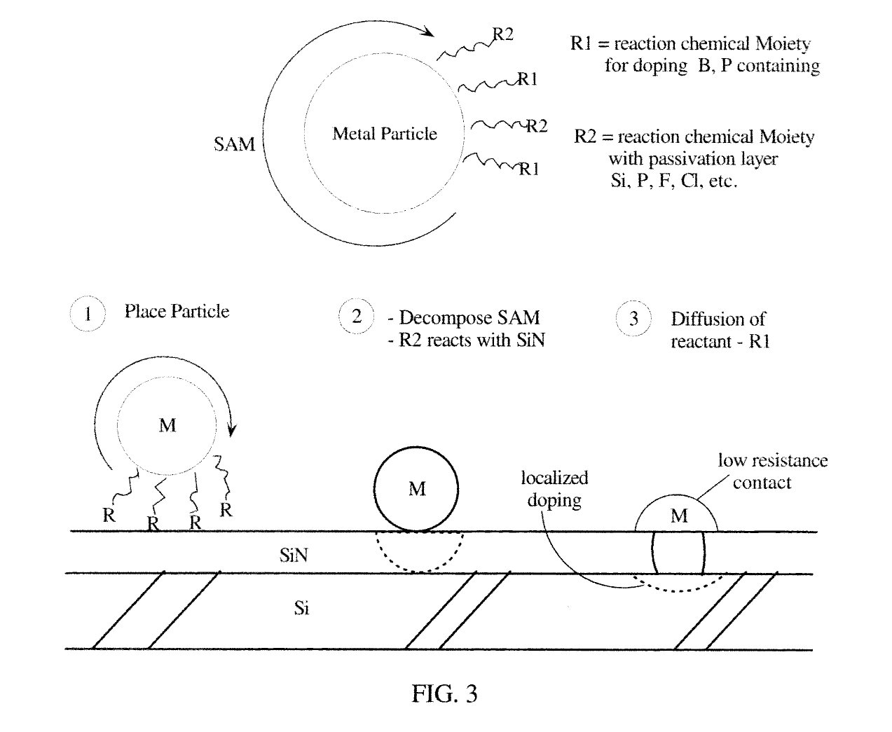

Referring to FIG. 3, in another embodiment, the nanoparticle is modified with a multi-functional surface layer, which reacts to :form a diffusion channel and diffuses metals for doping the silicon. This particle may be modified with a combination of the functionalities listed above. There may be any combination of multiple functionalities to react: with a passivation layer and also form a diffusion layer.

Referring again to FIG. 3, the derivatized metal particle is placed on the surface. The substrate contains a passivation layer, which may he silicon nitride. The substrate is heated to a high temperature. The components of the SAM gain surface mobility on the metal particle due to thermal energy. The SAM components migrate off the particle and onto the silicon nitride-coated substrate. The first component reacts to form a diffusion channel. As the substrate temperature is increased, subsequent components of the SAM diffuse into the silicon through the previously formed diffusion channel. This diffusion layer creates a local doping effect at the location of the particle placement. During this process, the metal particle begins to melt and die metal forms a contact at the exact location of the doping interface.

What is claimed is:

1. A method for metallization on a substrate comprising:
depositing a passivation layer on a silicon substrate;
depositing derivatized metal particles onto the passive layer;
heating the substrate of the solar cell to migrate surface coatings from the derivatized metal particles onto the passivation layer creating a diffusion channel through the passivation layer to the silicon substrate; and
as the metal particles melt due to the heating on the substrate, the melted metal diffuses through the diffusion channel forming a metallic content with the silicon substrate.

2. The method as recited in claim 1, wherein the passivation layer comprises silicon. nitride, and wherein the surface coatings contain a chemical functionality that reacts with the silicon nitride to form the diffusion channel.

3. The method as recited in claim 1, wherein the surface coatings are selected from a group consisting of silanes, trisilanes, polysilanes, disilaethenes, sioxanes, siloxane oligomers, and polysiloxanes.

4. The method as recited in claim 2, wherein the surface coatings decompose into silicon-based glass materials to facilitate a reaction with the silicon nitride.

5. The method as recited in claim 1, wherein the derivatized metal particles are produced by applying the surface coatings to the metal particles as self-assembled monolayers.

6. The method as recited in claim 1, wherein the surface coatings include one or more the following compounds selected from the group consisting of organo-borons, organo-phosphorous, organo-fluorine, and organo-chlorine compounds.

7. The method as recited in claim 1, wherein the metal particle is selected from the group consisting of Ag, Al, Cu, and Ni.

8. The method as recited in claim 1, wherein the derivatized metal particles are further coated with a compound that has a reactive chemical moiety for doping silicon, the method further comprising the compound diffuse through the diffusion channel to dope the silicon substrate.

9. The method as recited in claim 1, wherein the silicon substrate is part of a solar cell.
